(19) United States
(12) Patent Application Publication
(10) Pub. No.: US 2019/0033713 A1
(43) Pub. Date: Jan. 31, 2019

(54) RADIATION-SENSITIVE COMPOSITION AND PATTERN-FORMING METHOD

(71) Applicants: JSR CORPORATION, Tokyo (JP); CORNELL UNIVERSITY, Ithaca, NY (US)

(72) Inventors: Kazuki KASAHARA, Tokyo (JP); Vasiliki Kosma, Ithaca, NY (US); Mufei Yu, Ithaca, NY (US); Emmanuel P. Giannelis, Ithaca, NY (US); Christopher K. Ober, Ithaca, NY (US)

(73) Assignees: JSR CORPORATION, Tokyo (JP); CORNELL UNIVERSITY, Ithaca, NY (US)

(21) Appl. No.: 16/145,499

(22) Filed: Sep. 28, 2018

Related U.S. Application Data
(63) Continuation of application No. PCT/JP2017/007484, filed on Feb. 27, 2017.
(60) Provisional application No. 62/314,019, filed on Mar. 28, 2016.

(51) Int. Cl. G03F 7/004; G03F 7/16; G03F 7/32; G03F 7/20

(52) U.S. Cl. CPC G03F 7/0043; G03F 7/162; G03F 7/325; G03F 7/168; G03F 7/2004; G03F 7/2037; G03F 7/0045; G03F 7/322

(57) ABSTRACT

A radiation-sensitive composition includes a metal-containing component and an organic solvent. The metal-containing component includes particles including a metal oxide as a principal component. The metal-containing component includes at least two metal atoms which are different from one another, and a percentage content of the at least two metal atoms with respect to an entirety of metal atoms and metalloid atoms in the composition is no less than 50 atom %. The metal-containing component preferably includes: a first metal atom that is at least one selected from a titanium atom, a zirconium atom, a hafnium atom, a zinc atom, a tin atom and an indium atom; and a second metal atom that is at least one selected from a lanthanum atom and an yttrium atom.

### CROSS-REFERENCE TO RELATED APPLICATIONS

The present application is a continuation application of International Application No. PCT/JP2017/007484, filed Feb. 27, 2017, which claims priority to U.S. Provisional Patent Application No. 62/314,019, filed Mar. 28, 2016. The contents of these applications are incorporated herein by reference in their entirety.

### BACKGROUND OF THE INVENTION

### Field of the Invention

The present invention relates to a radiation-sensitive composition and a pattern-forming method.

### Discussion of the Background

A typical radiation-sensitive composition for use in microfabrication by lithography generates an acid upon an irradiation with an electromagnetic wave such as a far ultraviolet ray e.g., an ArF excimer laser beam, a KrF excimer laser beam, etc. and an extreme ultraviolet ray (EUV), a charged particle ray such as an electron beam, or the like at a light-exposed region. A chemical reaction in which the acid serves as a catalyst causes the difference in rates of dissolution in a developer solution, between light-exposed regions and light-unexposed regions to form a pattern on a substrate. The pattern thus formed can be used as a mask or the like in substrate processing.

Miniaturization in processing techniques has been accompanied by demands for improved resist performances of such radiation-sensitive compositions. To address the demands, types, molecular structures and the like of polymers, acid generating agents and other components to be used in a composition have been studied, and combinations thereof have also been extensively studied (refer to Japanese Unexamined Patent Application, Publication Nos. H11-125907, H8-146610, and 2000-298347).

### SUMMARY OF THE INVENTION

According to an aspect of the present invention, a radiation-sensitive composition includes a metal-containing component and an organic solvent. The metal-containing component includes particles including a metal oxide as a principal component. The metal-containing component includes at least two metal atoms which are different from one another, and a percentage content of the at least two metal atoms with respect to an entirety of metal atoms and metalloid atoms in the composition is no less than 50 atom %.

According to another aspect of the present invention, a pattern-forming method includes applying the radiation-sensitive composition on a substrate to form a film, exposing the film, and developing the film exposed.

### DESCRIPTION OF EMBODIMENTS

Currently, microfabrication of a pattern has thus proceeded to a level for a line width of no greater than 40 nm, and radiation-sensitive compositions are required to have further improved resist performances, particularly to be able to form with high sensitivity a pattern superior in resolution.

According to one embodiment of the invention made, a radiation-sensitive composition comprises: a metal-containing component (hereinafter, may be also referred to as “(A) metal-containing component” or “metal-containing component (A)”) comprising particles (hereinafter, may be also referred to as “(x) particles” or “particles (x)”) comprising a metal oxide as a principal component; and an organic solvent (hereinafter, may be also referred to as “(B) organic solvent” or “organic solvent (B)”), in which the metal-containing (A) component comprises at least two different metal atoms, and a percentage content of the metal atoms with respect to an entirety of the metal atoms and metalloid atoms in the composition is no less than 50 atom %.

According to another embodiment of the invention made, a pattern-forming method comprises: applying the radiation-sensitive composition according to the one embodiment on a substrate to form a film; exposing the film; and developing the film exposed.

The term “metal oxide” as referred to means a compound that comprises at least a metal atom and an oxygen atom. The term “principal component” as referred to means a component which is of the highest content, for example, a component the content of which is no less than 50% by mass. The term “particles” as referred to means, for example, a substance that has a mean particle diameter of no less than 1 nm. The term “metalloid atom” as referred to means a boron atom, a silicon atom, a germanium atom, and an arsenic atom.

The radiation-sensitive composition and the pattern-forming method according to the embodiments of the present invention enable a pattern superior in resolution to be formed with high sensitivity. Therefore, these can be suitably used for a processing process of semiconductor devices, and the like, in which further progress of miniaturization is expected in the future.

### Radiation-Sensitive Composition

The radiation-sensitive composition contains (A) a metal-containing component and (B) an organic solvent. The radiation-sensitive composition may also contain (C) a radiation-sensitive acid generator (hereinafter, may be also referred to as “(C) acid generator” or “acid generator (C)”) as a favorable component, and may also contain other optional components within a range not leading to impairment of the effects of the present invention. A percentage content of the metal atoms with respect to an entirety of the metal atoms and the metalloid atoms in the composition is no less than 50 atom %.

The radiation-sensitive composition enables a pattern superior in resolution to be formed with high sensitivity, due to including the metal-containing component (A) containing (x) particles, with at least two different metal atoms being included in the metal-containing component (A), and the organic solvent (B), and due to the percentage content of the metal atoms with respect to the entirety of metal atoms and metalloid atoms in the composition being no less than the lower limit. Although not necessarily clarified and without wishing to be bound by any theory, the reason for achieving the effects described above due to the radiation-sensitive composition having the aforementioned constitution is inferred as in the following, for example. Specifically, it is believed that the metal atoms contained in the metal-containing component (A) absorb exposure light to release secondary electrons, and then an action of the secondary electrons causes a structural change of the metal-containing component (A), whereby the solubility of the metal-containing component (A) in the developer solution is changed in the light-exposed region and thus pattern formation with high sensitivity is enabled. In addition, due to the metal-containing component (A) containing at least two different metal atoms, symmetry of the metal-containing component (A) such as the particles (x) would be reduced, and consequently an amorphous state suited for lithography would be more likely to be maintained and thus superior resolution is believed to be achieved.

The lower limit of the percentage content of the metal atoms with respect to the entirety of the metal atoms and the metalloid atoms in the radiation-sensitive composition is 50 atom %, preferably 70 atom %, more preferably 90 atom %, and still more preferably 99 atom %. When the percentage content of the metal atoms is no less than the lower limit, more effective promotion of the generation of the secondary electrons by the metal atoms contained in the metal-containing component (A) is enabled, whereby more improvements of the sensitivity and resolution of the radiation-sensitive composition are enabled. It is to be noted that the percentage content of the metal atoms may be 100 atom %.

### (A) Metal-Containing Component

The metal-containing component (A) contains the particles (x), with at least two different metal atoms being included in the metal-containing component (A). The metal-containing component (A) may contain, as a component containing a metal atom, either only the particles (x), or another component (hereinafter, may be also referred to as “(y) component” or “component (y)”) in addition to the particles (x). In the case in which the metal-containing component (A) contains only the particles (x) as the component containing a metal atom, the particles (x) contains at least two different metal atoms. In the case in which the metal-containing component (A) contains the particles (x) and the component (y) as the component containing a metal atom, the particles (x) and the component (y) each contain at least one metal atom, such that the entirety of the particles (x) and the component (y) contains at least two different metal atoms.

In other words, the constitution of the metal-containing component (A) is exemplified by constitutions (i) and (ii) described below and the like.

(i) Containing only the particles (x) containing at least two different metal atoms; and

(ii) Containing the particles (x) containing at least one metal atom and the component (y) containing at least one metal atom such that the entirety of the particles (x) and the component (y) contains at least two different metal atoms. Of these, the constitution (i) is preferred from the perspective that a further reduction in the symmetry in the metal-containing component (A) and more improvements of sensitivity and resolution of the radiation-sensitive composition are enabled.

The metal atoms contained in the metal-containing component (A) are exemplified by metal atoms from groups 3 to 6, and the like.

Examples of the metal atoms from group 3 include a scandium atom, an yttrium atom, a lanthanum atom, a cerium atom and the like.

Examples of the metal atoms from group 4 include a titanium atom, a zirconium atom, a hafnium atom and the like.

Examples of the metal atoms from group 5 include a vanadium atom, a niobium atom, a tantalum atom and the like.

Examples of the metal atoms from group 6 include a chromium atom, a molybdenum atom, a tungsten atom and the like.

Examples of the metal atoms from group 7 include a manganese atom, a rhenium atom and the like.

Examples of the metal atoms from group 8 include an iron atom, a ruthenium atom, an osmium atom and the like.

Examples of the metal atoms from group 9 include a cobalt atom, a rhodium atom, an iridium atom and the like.

Examples of the metal atoms from group 10 include a nickel atom, a palladium atom, a platinum atom and the like.

Examples of the metal atoms from group 11 include a copper atom, a silver atom, a gold atom and the like.

Examples of the metal atoms from group 12 include a zinc atom, a cadmium atom, a mercury atom and the like.

Examples of the metal atoms from group 13 include an aluminum atom, a gallium atom, an indium atom and the like.

Examples of the metal atoms from group 14 include a germanium atom, a tin atom, a lead atom and the like.

Examples of the metal atoms from group 15 include an antimony atom, a bismuth atom and the like.

Examples of the metal atoms from group 16 include a tellurium atom and the like.

Of these, as the metal atoms contained in the metal-containing component (A), the metal atoms from groups 3, 4, 9, 10, 11, 12, 13, 14, 15 and 16 are preferred, and a lanthanum atom, an yttrium atom, a titanium atom, a zirconium atom, a hafnium atom, a cobalt atom, a nickel atom, a platinum atom, a copper atom, a silver atom, a zinc atom, an indium atom, a tin atom, an antimony atom, a bismuth atom and a tellurium atom are more preferred. When the metal atoms exemplified above are contained in the metal-containing component, a more effective promotion of generation of the secondary electrons and a more increase in the contrast of the rate of dissolution in the developer solution between the light-exposed regions and the light-unexposed regions of the film formed from the radiation-sensitive composition of the present embodiment are enabled.

As the at least two different metal atoms contained in the metal-containing component (A), preferred is a combination of: a first metal atom (hereinafter, may be also referred to as “metal atom (1)”) which is at least one selected from a titanium atom, a zirconium atom, a hafnium atom, a zinc atom, a tin atom and an indium atom; and a second metal atom (hereinafter, may be also referred to as “metal atom (2)”) which is at least one selected from a lanthanum atom and an yttrium atom. When the metal atoms contained in the metal-containing component (A) are the above combination, the symmetry in the metal-containing component (A) is believed to be more reduced, and in turn more improvements of the sensitivity and resolution of the radiation-sensitive composition are enabled. Of these, as the metal atom (1), a combination including at least one selected from a zirconium atom and a hafnium atom is preferred, and a combination of a zirconium atom and a lanthanum atom, and a combination of a hafnium atom and an yttrium atom are more preferred.

In this case, the lower limit of a percentage content of the metal atom (2) with respect to the entirety of the metal atom (1) and the metal atom (2) is preferably 1 atom %, more preferably 3 atom %, still more preferably 5 atom %, and particularly preferably 10 atom %. The upper limit of the percentage content the metal atom (2) is preferably 50 atom %, more preferably 40 atom %, still more preferably 30 atom %, and particularly preferably 25 atom %. When the percentage content of the metal atom (2) falls within the above range, the symmetry in the metal-containing component (A) is believed to be further reduced, and in turn further improvements of the sensitivity and resolution of the radiation-sensitive composition are enabled.

As the at least two different metal atoms contained in the metal-containing component (A), also preferred is a third metal atom (hereinafter, may be also referred to as “metal atom (3)”) which is at least two selected from a titanium atom, a cobalt atom, a nickel atom, a copper atom, a silver atom, a platinum atom, a zirconium atom, a zinc atom, a tin atom, an indium atom, a tellurium atom, a bismuth atom, an antimony atom and a hafnium atom, and more preferred is the third metal atom which is at least two selected from a zirconium atom, a zinc atom, a tin atom, an indium atom, and a hafnium atom. When the metal atoms contained in the metal-containing component (A) are the above combination, the symmetry in the metal-containing component (A) is believed to be more reduced, and in turn more improvements of the sensitivity and resolution of the radiation-sensitive composition are enabled. Of these, preferred as the metal atom (3) is a combination of: a zirconium atom or a hafnium atom; and a zinc atom, an indium atom or a tin atom.

In this case, the lower limit of a percentage content of the metal atom (3) with respect to the entirety of the metal atoms in the radiation-sensitive composition of the present embodiment is preferably 50 atom %, more preferably 60 atom % and still more preferably 70 atom %. The upper limit of the percentage content of the metal atom (3) is, for example, 100 atom %. When the percentage content of the metal atom (3) falls within the above range, the symmetry in the metal-containing component (A) is believed to be further reduced, and in turn further improvements of the sensitivity and resolution of the radiation-sensitive composition are enabled.

Hereinafter, the particles (x) and the component (y) will be explained.

### (x) Particles

The particles (x) include a metal oxide as a principal component. It is to be noted that since the particles (x) include the metal oxide as the principal component, the particles (x) contribute also to improving etching resistance of a pattern formed from the radiation-sensitive composition of the embodiment of the present invention.

The lower limit of a mean particle diameter of the particles (x) is preferably 1.1 nm, and more preferably 1.2 nm. Meanwhile, the upper limit of the mean particle diameter of the particles (x) is preferably 20 nm, more preferably 10 nm, still more preferably 3.0 nm, and particularly preferably 2.5 nm. When the mean particle diameter of the particles (x) falls within the above range, a more effective promotion of the generation of the secondary electrons by the particles (x), and in turn a more improvement of the sensitivity and resolution of the radiation-sensitive composition are enabled. The “mean particle diameter” as referred to herein means a harmonic mean particle size on the basis of scattered light intensity, as measured by DLS (Dynamic Light Scattering) using a light scattering measurement device.

### Metal Oxide

The metal atom constituting the metal oxide included in the particles (x) is exemplified by metal atoms similar to those exemplified in connection with the metal atoms constituting the metal-containing component (A), and the like.

The metal oxide may contain an additional atom, other than the metal atom and an oxygen atom. Examples of the additional atom include metalloid atoms such as a boron atom and a germanium atom; a carbon atom; a hydrogen atom; a nitrogen atom; a phosphorus atom; a sulfur atom; a halogen atom; and the like. In the case of the metal oxide including the metalloid atom, the percentage content (% by mass) of the metalloid atom in the metal oxide is typically less than the percentage content of the metal atom.

The lower limit of a total percentage content of the metal atom and the oxygen atom in the metal oxide is preferably 30% by mass, more preferably 50% by mass, still more preferably 70% by mass, and particularly preferably 90% by mass. Meanwhile, the upper limit of the total percentage content of the metal atom and the oxygen atom is preferably 99.9% by mass. When the total percentage content of the metal atom and the oxygen atom falls within the above range, a more effective promotion of the generation of the secondary electrons by the particles (x), and in turn a more improvement of the sensitivity of the radiation-sensitive composition of the present embodiment are enabled. It is to be noted that the total percentage content of the metal atom and the oxygen atom may be 100% by mass.

A component other than the metal atoms constituting the metal oxide is preferably (a) an organic acid. The “organic acid” as referred to herein means an acidic organic compound, and the “organic compound” as referred to means a compound having at least one carbon atom.

When the particles (x) contain the metal oxide constituted from the metal atom and the organic acid (a), more improvements of the sensitivity and resolution of the radiation-sensitive composition of the present embodiment are enabled. Although not necessarily clarified and without wishing to be bound by any theory, the reason for achieving the effects described above due to the radiation-sensitive composition having the aforementioned constitution is inferred as in the following, for example. Specifically, the organic acid (a) being present in the vicinity of surfaces of the particles (x) due to an interaction with the metal atom is believed to improve dispersibility of the particles (x) in the solvent. As a result, the sensitivity of the radiation-sensitive composition is believed to be more improved.

The lower limit of pKa of the organic acid (a) is preferably 0, more preferably 1, still more preferably 1.5, and particularly preferably 3. Meanwhile, the upper limit of the pKa is preferably 7, more preferably 6, still more preferably 5.5, and particularly preferably 5. When the pKa of the organic acid (a) falls within the above range, it is possible to adjust the interaction with the metal atom to be moderately weak, whereby more improvements of the sensitivity and resolution of the radiation-sensitive composition are enabled. As used herein, in the case of the organic acid (a) being a polyvalent acid, the pKa of the organic acid (a) as referred to means a primary acid dissociation constant, i.e., a logarithmic value of a dissociation constant for dissociation of the first proton.

The organic acid (a) may be either a low molecular weight compound or a high molecular weight compound, and a low molecular weight compound is preferred in light of adjusting the interaction with the metal atom to be more appropriately weak. The “low molecular weight compound” as referred to means a compound having a molecular weight of no greater than 1,500, whereby the “high molecular weight compound” as referred to means a compound having a molecular weight of greater than 1,500. The lower limit of the molecular weight of the organic acid (a) is preferably 50, and more preferably 80. Meanwhile, the upper limit of the molecular weight is preferably 1,000, more preferably 500, further more preferably 400, and particularly preferably 300. When the molecular weight of the organic acid (a) falls within the above range, it is possible to adjust the dispersibility of the particles (x) to be more appropriate, and consequently more improvements of the sensitivity and resolution of the radiation-sensitive composition of the present embodiment are enabled.

The organic acid (a) is exemplified by a carboxylic acid, a sulfonic acid, a sulfinic acid, an organic phosphinic acid, an organic phosphonic acid, a phenol, an enol, a thiol, an acid imide, an oxime, a sulfonamide, and the like.

Examples of the carboxylic acid include:

monocarboxylic acids such as formic acid, acetic acid, propionic acid, butanoic acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, benzoic acid, p-aminobenzoic acid, monochloroacetic acid, dichloroacetic acid, trichloroacetic acid, trifluoroacetic acid, pentafluoropropionic acid, gallic acid and shikimic acid;

dicarboxylic acids such as oxalic acid, malonic acid, maleic acid, methylmalonic acid, fumaric acid, adipic acid, sebacic acid, phthalic acid and tartaric acid;

carboxylic acids having no less than 3 carboxy groups such as citric acid; and the like.

Examples of the sulfonic acid include benzenesulfonic acid, p-toluenesulfonic acid, and the like.

Examples of the sulfinic acid include benzenesulfinic acid, p-toluenesulfinic acid, and the like.

Examples of the organic phosphinic acid include diethylphosphinic acid, methylphenylphosphinic acid, diphenylphosphinic acid, and the like.

Examples of the organic phosphonic acid include methylphosphonic acid, ethylphosphonic acid, t-butylphosphonic acid, cyclohexylphosphonic acid, phenylphosphonic acid, and the like.

Examples of the phenol include: monovalent phenols such as phenol, cresol, 2,6-xylenol and naphthol;

divalent phenols such as catechol, resorcinol, hydroquinone and 1,2-naphthalenediol;

phenols having a valency of no less than 3 such as pyrogallol and 2,3,6-naphthalenetriol; and the like.

Examples of the enol include 2-hydroxy-3-methyl-2-butene, 3-hydroxy-4-methyl-3-hexene, and the like.

Examples of the thiol include mercaptoethanol, mercaptopropanol, and the like.

Examples of the acid imide include:

carboxylic imides such as maleimide and succinimide;

sulfonic imides such as a di(trifluoromethanesulfonic acid) imide and di(pentafluoroethanesulfonic acid) imide; and the like.

Examples of the oxime include:

aldoximes such as benzaldoxime and salicylaldoxime;

ketoximes such as diethylketoxime, methylethylketoxime and cyclohexanoneoxime; and the like.

Examples of the sulfonamide include methylsulfonamide, ethylsulfonamide, benzenesulfonamide, toluenesulfonamide, and the like.

In light of more improving the sensitivity and resolution of the radiation-sensitive composition, as the organic acid (a), the carboxylic acid is preferred; the monocarboxylic acid is more preferred; and methacrylic acid and benzoic acid are still more preferred.

As the metal oxide, a metal oxide constituted from a metal atom and the organic acid (a) is preferred, a metal oxide constituted from at least two different metal atoms and the organic acid (a) is more preferred, a metal oxide constituted from: a zinc atom or a hafnium atom; a zinc atom, an indium atom or a tin atom; and a methacrylic acid or a benzoic acid is still more preferred, and a metal oxide constituted from: a zirconium atom; a zinc atom, an indium atom or a tin atom; and a methacrylic acid, and a metal oxide constituted from: a hafnium atom; a zinc atom, an indium atom or a tin atom; and a benzoic acid are particularly preferred.

The lower limit of a percentage content of the metal oxide in the particles (x) is preferably 60% by mass, more preferably 80% by mass, and further more preferably 95% by mass. It is to be noted that the percentage content of the metal oxide may be 100% by mass. When the content of the metal oxide is no less than the lower limit, more improvements of the sensitivity and resolution of the radiation-sensitive composition are enabled. It is to be noted that the radiation-sensitive composition may include either only one type, or two or more types of the metal oxide.

In the case in which the particles (x) contain as the principal component, the metal oxide, which is constituted from the metal atom and the organic acid (a), the lower limit of a percentage content of the organic acid (a) in the particles (x) is preferably 1% by mass, more preferably 5% by mass, and still more preferably 10% by mass. Meanwhile, the upper limit of the percentage content of the organic acid (a) is preferably 90% by mass, more preferably 70% by mass, and still more preferably 50% by mass. When the percentage content of the organic acid (a) falls within the above range, it is possible to adjust the dispersibility of the particles (x) to be further appropriate, and consequently more improvements of the sensitivity and resolution of the radiation-sensitive composition of the present embodiment are enabled. The particles (x) may include either only one type, or two or more types of the organic acid (a).

The lower limit of the content of the particles (x) with respect to the metal-containing component (A) is preferably 10% by mass, more preferably 50% by mass, still more preferably 70% by mass, and particularly preferably 85% by mass. Meanwhile, the upper limit of the content of the particles (x) with respect to the metal-containing component (A) is preferably 99% by mass, and more preferably 95% by mass. When the content of the particles (x) falls within the above range, more improvements of the sensitivity and resolution of the radiation-sensitive composition are enabled. The radiation-sensitive composition may include either only one type, or two or more types of the particles (x).

### Synthesis Procedure of (x) Particles

The particles (x) may be obtained by, for example, a procedure of carrying out a hydrolytic condensation reaction by using (b) a metal-containing compound, a procedure of carrying out a ligand substitution reaction by using the metal-containing compound (b), or the like. The “hydrolytic condensation reaction” as referred to means a reaction in which a hydrolyzable group comprised in the metal-containing compound (b) is hydrolyzed to give —OH, and two —OHs thus obtained undergo dehydrative condensation to form —O—.

### Metal-Containing Compound (b)

The metal-containing compound (b) is: a metal compound (I) having a hydrolyzable group; a hydrolysis product of the metal compound (I) having a hydrolyzable group; a hydrolytic condensation product of the metal compound (I) having a hydrolyzable group; or a combination thereof. The metal compound (I) may be used either alone of one type, or in combination of two or more types thereof.

The hydrolyzable group is exemplified by a halogen atom, an alkoxy group, an acyloxy group, and the like.

Examples of the halogen atom include a fluorine atom, a chlorine atom, a bromine atom, an iodine atom, and the like.

Examples of the alkoxy group include a methoxy group, an ethoxy group, a n-propoxy group, an i-propoxy group, a butoxy group, and the like.

Examples of the acyloxy group include an acetoxy group, an ethylyloxy group, a propionyloxy group, a butyryloxy group, a t-butyryloxy group, a t-amylyloxy group, a n-hexanecarbonyloxy group, a n-octanecarbonyloxy group, and the like.

As the hydrolyzable group, an alkoxy group and an acyloxy group are preferred, and an isopropoxy group and an acetoxy group are more preferred.

In a case in which the metal-containing compound (b) is a hydrolytic condensation product of the metal compound (I), the hydrolytic condensation product of the metal compound (I) may be a hydrolytic condensation product of the metal (I) having a hydrolyzable group with a compound including a metalloid atom, within a range not leading to impairment of the effects of the embodiments of the present invention. In other words, the hydrolytic condensation product of the metal compound (I) may also include a metalloid atom within a range not leading to impairment of the effects of the embodiments of the present invention. The metalloid atom is exemplified by a boron atom, a germanium atom, an antimony atom, an arsenic atom and the like. The percentage content of the metalloid atom in the hydrolytic condensation product of the metal compound (I) is typically less than 50 atom % with respect to the entirety of the metal atom and the metalloid atom in the hydrolytic condensation product. The upper limit of the percentage content of the metalloid atom is preferably 30 atom % and more preferably 10 atom % with respect to the entirety of the metal atom and the metalloid atom in the hydrolytic condensation product.

The metal compound (I) is exemplified by compounds represented by the following formula (1) (hereinafter, may be also referred to as a “metal compound (I-1)”), and the like. By using the metal compound (I-1), forming a stable metal oxide is enabled, whereby more improvements of the sensitivity and resolution of the radiation-sensitive composition are enabled.

LₐMY_{b} (1)

In the above formula (1), M represents a metal atom; L represents a ligand; a is an integer of 0 to 2, wherein in a case where a is 2, a plurality of Ls may be identical or different; Y represents a hydrolyzable group selected from a halogen atom, an alkoxy group and an acyloxy group; b is an integer of 2 to 6; and a plurality of Ys may be identical or different. It is to be noted that L is a ligand that does not fall under the definition of Y.

The metal atom represented by M is exemplified by metal atoms similar to those exemplified in connection with the metal atoms which may constitute the metal oxide included in the particles (x), and the like.

The ligand represented by L is exemplified by a monodentate ligand and a polydentate ligand.

Exemplary monodentate ligand includes a hydroxo ligand, a carboxy ligand, an amido ligand, ammonia, and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like.

Exemplary polydentate ligand includes a hydroxy acid ester, a β-diketone, a β-keto ester, a β-dicarboxylic acid ester, a hydrocarbon having a π bond, a diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the β-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a π bond include:

chain olefins such as ethylene and propylene;

cyclic olefins such as cyclopentene, cyclohexene and norbornene;

chain dienes such as butadiene and isoprene;

cyclic dienes such as cyclopentadiene, methylcyclopentadiene, pentamethylcyclopentadiene, cyclohexadiene and norbornadiene;

aromatic hydrocarbons such as benzene, toluene, xylene, hexamethylbenzene, naphthalene and indene; and the like.

Examples of the diphosphine includes 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

Examples and preferred examples of the halogen atom, the alkoxy group and the acyloxy group that may be represented by Y may be similar to those explained in connection with the hydrolyzable group.

Preferably, b is 3 or 4, and more preferably 4. When b is the above specified value, it is possible to increase the percentage content of the metal oxide in the particles (x), whereby more effective promotion of the generation of the secondary electrons by the particles (x) is enabled. Consequently, a more improvement of the sensitivity of the radiation-sensitive composition is enabled.

As the metal-containing compound (b), a metal alkoxide that is neither hydrolyzed nor hydrolytic condensed, and a metal acyloxide that is neither hydrolyzed nor hydrolytically condensed are preferred.

Examples of the metal-containing compound (b) include zirconium(IV) n-butoxide, zirconium(IV) n-propoxide, zirconium(IV) isopropoxide, hafnium(IV) ethoxide, indium(III) isopropoxide, hafnium(IV) isopropoxide, tantalum(V) ethoxide, tungsten(V) methoxide, tungsten(VI) ethoxide, iron chloride, zinc(II) isopropoxide, zinc acetate dihydrate, titanium(IV) n-butoxide, titanium(IV) n-propoxide, zirconium(IV) di-n-butoxide bis(2,4-pentanedionate), titanium(IV) tri-n-butoxide stearate, bis(cyclopentadienyl)hafnium(IV) dichloride, bis(cyclopentadienyl)tungsten(IV) dichloride, diacetato[(S)-(−)-2,2′-bis(diphenylphosphino)-1,1′-binaphtyl]ruthenium(II), dichloro[ethylenebis(diphenylpho sphine)]cobalt(II), a titanium butoxide oligomer, aminopropyltrimethoxytitanium(IV), aminopropyltriethoxyzirconium(IV), 2-(3,4-epoxycyclohexyl)ethyltrimethoxyzirconium(IV), γ-glycidoxypropyltrimethoxyzirconium(IV), 3-isocyanopropyltrimethoxyzirconium(IV), 3-isocyanopropyltriethoxyzirconium(IV), triethoxymono(acetylacetonato)titanium(IV), tri-n-propoxymono(acetylacetonato)titanium(IV), tri-i-propoxymono(acetylacetonato)titanium(IV), triethoxymono(acetylacetonato)zirconium(IV), tri-n-propoxymono(acetylacetonato)zirconium(IV), tri-i-propoxymono(acetylacetonato)zirconium(IV), diisopropoxybis(acetylacetonato)titanium(IV), di-n-butoxybis(acetylacetonato)titanium(IV), di-n-butoxybis(acetylacetonato)zirconium(IV), tri(3-methacryloxypropyl)methoxyzirconium(IV), tri(3-acryloxypropyl)methoxyzirconium(IV), tin(IV) isopropoxide, lanthanum(III) oxide, yttrium(III) oxide and the like. Of these, zirconium(IV) isopropoxide, hafnium(IV) isopropoxide, zinc(II) isopropoxide, indium(III) isopropoxide, tin(IV) isopropoxide, lanthanum(III) oxide and yttrium(III) oxide are preferred.

A procedure for carrying out the hydrolytic condensation reaction using the metal-containing compound (b) may be exemplified by: a procedure of hydrolytically condensing the metal-containing compound (b) in a solvent containing water; and the like. In this case, other compound having a hydrolyzable group may be added as needed. The lower limit of the amount of water used for the hydrolytic condensation reaction is preferably 0.2 times molar amount, more preferably an equimolar amount, and still more preferably 3 times molar amount with respect to the hydrolyzable group included in the metal-containing compound (b) and the like. The upper limit of the amount of water is preferably 20 times molar amount, more preferably 15 times molar amount, and further more preferably 10 times molar amount. When the amount of the water in the hydrolytic condensation reaction falls within the above range, it is possible to increase the percentage content of the metal oxide in the particles (x) to be obtained, whereby more improvements of the sensitivity and resolution of the radiation-sensitive composition are enabled.

A procedure for carrying out the ligand substitution reaction using the metal-containing compound (b) may be exemplified by: a procedure of mixing the metal-containing compound (b) and the organic acid (a); and the like. In this case, the mixing may be carried out either in a solvent or without a solvent. Upon the mixing, a base such as triethylamine may be added as needed. An amount of the base added is, for example, no less than 1 part by mass and no greater than 200 parts by mass with respect to 100 parts by mass of a total amount of the metal-containing compound (b) and the organic acid (a) used.

In the case of using the organic acid (a) in synthesizing the particles (x), the lower limit of the amount of the organic acid (a) used is preferably 10 parts by mass, and more preferably 30 parts by mass with respect to 100 parts by mass of the metal-containing compound (b). Meanwhile, the upper limit of the amount of the organic acid (a) used is preferably 1,000 parts by mass, more preferably 700 parts by mass, still more preferably 200 parts by mass, and particularly preferably 100 parts by mass with respect to 100 parts by mass of the metal-containing compound (b). When the amount of the organic acid (a) used falls within the above range, an appropriate adjustment of a percentage content of the organic acid (a) in the particles (x) to be obtained is enabled, and consequently more improvements of the sensitivity and resolution of the radiation-sensitive composition are enabled.

Upon the synthesis reaction of the particles (x), in addition to the metal compound (I) and the organic acid (a), a compound that may be the polydentate ligand represented by L in the compound of the formula (1), a compound that may be a bridging ligand, etc., may also be added. The compound that may be the bridging ligand is exemplified by a compound having a hydroxy group, an isocyanate group, an amino group, an ester group and an amide group each in a plurality of number, and the like.

The solvent for use in the synthesis reaction of the particles (x) is not particularly limited, and solvents similar to those exemplified in connection with the solvent (B) described later may be used. Of these, alcohol solvents, ether solvents, ester solvents, and hydrocarbon solvents are preferred; alcohol solvents, ether solvents and ester solvents are more preferred; polyhydric alcohol partial ether solvents, monocarboxylic acid ester solvents and cyclic ether solvents are still more preferred; and propylene glycol monoethyl ether, ethyl acetate and tetrahydrofuran are particularly preferred.

In the case of using the solvent in the synthesis reaction of the particles (x), the solvent used may be either removed after the completion of the reaction, or directly used as the organic solvent (B) in the radiation-sensitive composition without removal thereof.

The lower limit of the temperature of the synthesis reaction of the particles (x) is preferably 0° C., and more preferably 10° C. The upper limit of the aforementioned temperature is preferably 150° C., and more preferably 100° C.

The lower limit of the time period of the synthesis reaction of the particles (x) is preferably 1 min, more preferably 10 min, and still more preferably 1 hour. The upper limit of the time period is preferably 100 hrs, more preferably 50 hrs, and further more preferably 10 hrs.

### (y) Component

The component (y) is a component that may constitute the metal-containing component (A) in addition to the particles (x). The component (y) is exemplified by a complex containing a metal atom, a metal salt, and the like.

Exemplary complex includes a compound containing a metal atom and a ligand, and the like. Examples of the ligand include ligands similar to those exemplified in connection with the ligand represented by L included in the metal compound (I-1), and the like.

Exemplary metal salt includes a compound having a metal cation and an anion, and the like. Examples of the anion include a sulfate anion, a sulfonate anion, a nitrate anion, a phosphate anion, a sulfonimide anion, a halide anion and the like. The halide anion may be, for example, a fluoride anion, a chloride anion, a bromide anion, an iodide anion, or the like.

In the case in which the metal-containing component (A) contains the component (y), the lower limit of the content of the component (y) with respect to 100 parts by mass of the particles (x) is preferably 1 part by mass, more preferably 10 parts by mass, still more preferably 30 parts by mass, and particularly preferably 50 parts by mass. The upper limit of the content is preferably 500 parts by mass, more preferably 300 parts by mass, still more preferably 200 parts by mass, and particularly preferably 100 parts by mass. When the content of the component (y) falls within the above range, more improvements of the sensitivity and resolution of the radiation-sensitive composition are enabled. The radiation-sensitive composition may include either only one type, or two or more types, of the component (y).

The lower limit of the content of the metal-containing component (A) with respect to the total solid content of the radiation-sensitive composition is preferably 70% by mass, more preferably 80% by mass, and still more preferably 85% by mass. The upper limit of the content is preferably 100% by mass, more preferably 99% by mass, and still more preferably 95% by mass. When the content of the metal-containing component (A) falls within the above range, more improvements of the sensitivity and resolution of the radiation-sensitive composition are enabled. The term “solid content” in the radiation-sensitive composition as referred to means the sum of the components other than the organic solvent (B).

### (B) Organic Solvent

The organic solvent (B) is not particularly limited as long as it is a solvent capable of dissolving or dispersing at least the metal-containing component (A), as well as optional component(s) included as needed. The organic solvent (B) may be used either alone of one type, or in combination of two or more types thereof.

The organic solvent (B) is exemplified by alcohol solvents, ether solvents, ketone solvents, amide solvents, ester solvents, hydrocarbon solvents, and the like.

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

C3-19 polyhydric alcohol partial ether solvents such as propylene glycol monomethyl ether; and the like.

Examples of the ether solvent include:

dialkyl ether solvents such as diethyl ether, dipropyl ether, dibutyl ether, dipentyl ether, diisoamyl ether, dihexyl ether and diheptyl ether;

cyclic ether solvents such as tetrahydrofuran and tetrahydropyran;

aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone and trimethylnonanone;

cyclic ketone solvents such as cyclopentanone, cyclohexanone, cycloheptanone, cyclooctanone and methylcyclohexanone;

2,4-pentanedione, acetonylacetone and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide and N-methylpropionamide; and the like.

Examples of the ester solvent include:

monocarboxylic acid ester solvents such as n-butyl acetate and ethyl lactate;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

Of these, the alcohol solvents, the ester solvents and the ketone solvents are preferred; the polyhydric alcohol partial ether solvents, the polyhydric alcohol partial ether carboxylate solvents and the cyclic ketone solvents are more preferred; the polyhydric alcohol partial ether solvents and the polyhydric alcohol partial ether carboxylate solvents are still more preferred; and propylene glycol monomethyl ether and propylene glycol monomethyl ether acetate are particularly preferred.

### (C) Radiation-Sensitive Acid Generator

The radiation-sensitive acid generator (C) (hereinafter, may be referred to as “acid generator (C)”), which is a favorable component of the radiation-sensitive composition of the present embodiment, is a component that generates an acid upon exposure to a radioactive ray. The acid generator (C) may be contained in the radiation-sensitive composition in the form of a low molecular weight compound (hereinafter, may be also referred to as “acid generating agent (C)” as appropriate), or in the form incorporated as a part of the metal-containing component (A), or in both of these forms; however, it is preferred that only the acid generating agent (C) is contained, in light of etching resistance.

The acid generating agent (C) is exemplified by an onium salt compound, an N-sulfonyloxyimide compound, a halogen-containing compound, a diazo ketone compound, and the like.

The onium salt compound is exemplified by a sulfonium salt, a tetrahydrothiophenium salt, an iodonium salt, a phosphonium salt, a diazonium salt, a pyridinium salt, and the like.

Examples of the sulfonium salt include: triphenylsulfonium trifluoromethanesulfonate, triphenylsulfonium nonafluoro-n-butanesulfonate, triphenylsulfonium perfluoro-n-octanesulfonate, triphenylsulfonium 2-bicyclo[2.2.1]hept-2-yl-1,1,2,2-tetrafluoroethanesulfonate, triphenylsulfonium camphorsulfonate, 4-cyclohexylphenyldiphenylsulfonium trifluoromethanesulfonate, 4-cyclohexylphenyldiphenylsulfonium nonafluoro-n-butanesulfonate, 4-cyclohexylphenyldiphenylsulfonium perfluoro-n-octanesulfonate, 4-cyclohexylphenyldiphenylsulfonium2-bicyclo[2.2.1]hept-2-yl-1,1,2,2-tetrafluoroethanesulfonate, 4-cyclohexylphenyldiphenylsulfonium camphorsulfonate, 4-methanesulfonylphenyldiphenylsulfonium trifluoromethanesulfonate, 4-methanesulfonylphenyldiphenylsulfonium nonafluoro-n-butanesulfonate, 4-methanesulfonylphenyldiphenylsulfonium perfluoro-n-octanesulfonate, 4-methanesulfonylphenyldiphenylsulfonium 2-bicyclo[2.2.1]hept-2-yl-1,1,2,2-tetrafluoroethanesulfonate, 4-methanesulfonylphenyldiphenylsulfonium camphorsulfonate, triphenylphosphonium 1,1,2,2-tetrafluoro-6-(1-adamantanecarbonyloxy)-hexane-1-sulfonate, triphenylsulfonium 2-(1-adamantyl)-1,1-difluoroethane sulfonate, triphenylsulfonium 2-(adamantane-1-yl carbonyloxy)-1,1,3,3,3-pentafluoropropane-1-sulfonate, and the like.

Examples of the tetrahydrothiophenium salt include 1-(4-n-butoxynaphthalen-1-yl)tetrahydrothiophenium trifluoromethanesulfonate, 1-(4-n-butoxynaphthalen-1-yl)tetrahydrothiophenium nonafluoro-n-butanesulfonate, 1-(4-n-butoxynaphthalen-1-yl)tetrahydrothiophenium perfluoro-n-octanesulfonate, 1-(4-n-butoxynaphthalen-1-yl)tetrahydrothiophenium 2-bicyclo[2.2.1]hept-2-yl-1,1,2,2-tetrafluoroethanesulfonate, 1-(4-n-butoxynaphthalen-1-yl)tetrahydrothiophenium camphorsulphonate, 1-(4-n-butoxynaphthalen-1-yl)tetrahydrothiophenium hexafluoropropylene sulfonimide, 1-(6-n-butoxynaphthalen-2-yl)tetrahydrothiophenium trifluoromethanesulfonate, 1-(6-n-butoxynaphthalen-2-yl)tetrahydrothiophenium nonafluoro-n-butanesulfonate, 1-(6-n-butoxynaphthalen-2-yl)tetrahydrothiophenium perfluoro-n-octanesulfonate, 1-(6-n-butoxynaphthalen-2-yl)tetrahydrothiophenium 2-bicyclo[2.2.1]hept-2-yl-1,1,2,2-tetrafluoroethanesulfonate, 1-(6-n-butoxynaphthalen-2-yl)tetrahydrothiophenium camphorsulphonate, 1-(6-n-butoxynaphthalen-2-yl)tetrahydrothiophenium hexafluoropropylene sulfonimide, 1-(3,5-dimethyl-4-hydroxyphenyl)tetrahydrothiophenium trifluoromethanesulfonate, 1-(3,5-dimethyl-4-hydroxyphenyl)tetrahydrothiophenium nonafluoro-n-butanesulfonate, 1-(3,5-dimethyl-4-hydroxyphenyl)tetrahydrothiophenium perfluoro-n-octanesulfonate, 1-(3,5-dimethyl-4-hydroxyphenyl)tetrahydrothiophenium 2-bicyclo[2.2.1]hept-2-yl-1,1,2,2-tetrafluoroethanesulfonate, 1-(3,5-dimethyl-4-hydroxyphenyl)tetrahydrothiophenium camphorsulfonate, 1-(3,5-dimethyl-4-hydroxyphenyl)tetrahydrothiophenium hexafluoropropylene sulfonimide, and the like.

Examples of the iodonium salt include: diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, diphenyliodonium camphorsulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, and the like.

Examples of the N-sulfonyloxyimide compound include N-(trifluoromethanesulfonyloxy)-1,8-naphthalimide, N-(trifluoromethanesulfonyloxy)bicyclo[2.2.1]hept-5-ene-2,3-dicarboxyimide, N-(nonafluoro-n-butanesulfonyloxy)bicyclo[2.2.1]hept-5-ene-2,3-dicarboxyimide, N-(perfluoro-n-octanesulfonyloxy)-1,8-naphthalimide, N-(perfluoro-n-octanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, N-(2-(3-tetracyclo[4.4.0.1^{2,5}.1^{7,10}]dodecanyl)-1,1-difluoroethanesulfonyloxy)bicyclo[2.2.1]hept-5-ene-2,3-dicarboxyimide, N-(camphorsulfonyloxy)bicyclo[2.2.1]hept-5-ene-2,3-dicarboxyimide, and the like.

As the acid generating agent (C), an onium salt compound and a N-sulfonyloxyimide compound are preferred; a sulfonium salt and a N-sulfonyloxyimide compound are more preferred; a triphenylsulfonium salt and N-sulfonyloxy-1,8-naphthalimide are further more preferred; and triphenylsulfonium trifluoromethanesulfonate and N-(trifluoromethanesulfonyloxy)-1,8-naphthalimide are particularly preferred.

In the case in which the radiation-sensitive composition of the present embodiment contains the acid generating agent (C) as the acid generator (C), the lower limit of a content of the acid generating agent (C) with respect to 100 parts by mass of the metal-containing compound (A) is preferably 0.1 parts by mass, more preferably 0.5 parts by mass, still more preferably 1 part by mass, and particularly preferably 3 parts by mass. The upper limit of the content is preferably 50 parts by mass, more preferably 30 parts by mass, still more preferably 20 parts by mass, and particularly preferably 15 parts by mass. When the content of the acid generating agent (C) falls within the above range, further improvements of the sensitivity and resolution of the radiation-sensitive composition are enabled. The acid generator (C) may be used either alone of one type, or in combination of two or more types thereof.

### Other Optional Component

The radiation-sensitive composition of the present embodiment may also comprise, in addition to the components (A) to (C), optional components such as a compound that may be a ligand, a surfactant, and the like. Each of these other optional components may be used either alone of one type, or in combination of two or more types thereof.

Compound that May be Ligand

The compound that may be a ligand to be used in the radiation-sensitive composition is exemplified by a compound that may be a polydentate ligand or a bridging ligand (hereinafter, may be also referred to as “compound (II)”) and the like. Examples of the compound (II) include compounds similar to those exemplified as the compounds that may be added upon the hydrolytic condensation reaction in the synthesis procedure of the particles (x), and the like.

In the case in which the radiation-sensitive composition contains the compound (II), the upper limit of the content of the compound (II) with respect to the total solid content in the radiation-sensitive composition is preferably 10% by mass, more preferably 3% by mass, and further more preferably 1% by mass.

The surfactant which may be used in the radiation-sensitive composition is a component that exhibits the effect of improving coating properties, striation and the like. Examples of the surfactant include: nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate and polyethylene glycol distearate; and the like. Examples of a commercially available product of the surfactant include KP341 (available from Shin-Etsu Chemical Co., Ltd.), Polyflow No. 75 and Polyflow No. 95 (each available from Kyoeisha Chemical Co., Ltd.), EFTOP EF301, EFTOP EF303 and EFTOP EF352 (each available from Tochem Products Co. Ltd.), Megaface F171 and Megaface F173 (each available from DIC Corporation), Fluorad FC430 and Fluorad FC431 (each available from Sumitomo 3M Limited), ASAHI GUARD AG710, Surflon S-382, Surflon SC-101, Surflon SC-102, Surflon SC-103, Surflon SC-104, Surflon SC-105 and Surflon SC-106 (each available from Asahi Glass Co., Ltd.), and the like.

### Preparation of Radiation-Sensitive Composition

The radiation-sensitive composition of the present embodiment may be prepared, for example, by mixing the metal-containing component (A) and the organic solvent (B), as well as the optional component such as the acid generator (C) as needed, at a certain ratio, preferably followed by filtering a mixture thus obtained through a filter having a pore size of 0.2 μm. The lower limit of the solid content concentration of the radiation-sensitive composition is preferably 0.1% by mass, more preferably 0.5% by mass, still more preferably 1% by mass, and particularly preferably 3% by mass. Meanwhile, the upper limit of the solid content concentration is preferably 50% by mass, more preferably 30% by mass, still more preferably 15% by mass, and particularly preferably 7% by mass.

### Pattern-Forming Method

The pattern-forming method of another embodiment of the present invention includes: applying the radiation-sensitive composition on one face side of a substrate to form a film (hereinafter, may be also referred to as “applying step”); exposing the film (hereinafter, may be also referred to as “exposure step”); and developing the film exposed (hereinafter, may be also referred to as “development step”). The radiation-sensitive composition of the embodiment of the present invention described above is employed in the pattern-forming method, and therefore the method enables a pattern superior in resolution to be formed with high sensitivity. Hereinafter, each step is explained.

### Applying Step

In this step, the radiation-sensitive composition is applied on a substrate to form a film. Specifically, the film is formed by applying the radiation-sensitive composition such that the resulting film has a desired thickness, followed by prebaking (PB) to volatilize the solvent and the like in the radiation-sensitive composition as needed. A procedure for applying the radiation-sensitive composition is not particularly limited, and an appropriate application procedure such as spin-coating, cast coating, roller coating, etc. may be employed. Examples of the substrate include a silicon wafer, a wafer coated with aluminum, and the like. It is to be noted that an organic or inorganic antireflective film may also be formed on the substrate in order to maximize potential of the radiation-sensitive composition.

The lower limit of an average thickness of the film to be formed in the present step is preferably 1 nm, more preferably 5 nm, further more preferably 10 nm, and particularly preferably 20 nm. Meanwhile, the upper limit of the average thickness is preferably 1,000 nm, more preferably 200 nm, further more preferably 100 nm, and particularly preferably 70 nm.

The lower limit of the temperature of the PB is typically 60° C., and preferably 80° C. The upper limit of the temperature of the PB is typically 140° C., and preferably 120° C. The lower limit of the time period of the PB is typically 5 sec, and preferably 10 sec. The upper limit of the time period of the PB is typically 600 sec, and preferably 300 sec.

In this step, in order to inhibit an influence of basic impurities, etc., in the environmental atmosphere, for example, a protective film may be provided on the film formed. Furthermore, in the case of conducting liquid immersion lithography in the exposing step as described later, in order to avoid a direct contact between a liquid immersion medium and the film, a protective film for liquid immersion may also be provided on the film formed.

### Exposure Step

In this step, the film obtained by the applying is exposed. Specifically, for example, the film is irradiated with a radioactive ray through a mask having a predetermined pattern. In this step, irradiation with a radioactive ray through a liquid immersion medium such as water, i.e., liquid immersion lithography, may be employed as needed. Examples of the radioactive ray for the exposure include: electromagnetic waves such as visible light rays, ultraviolet rays, far ultraviolet rays, EUV (wavelength: 13.5 nm), X-rays and γ-rays; charged particle rays such as electron beams and α-rays; and the like. Of these, EUV and electron beams are preferred in light of increasing the secondary electrons generated from the metal-containing component (A) having absorbed the radioactive ray.

### Development Step

In this step, the film exposed is developed by using a developer solution. A predetermined pattern is thereby formed. Examples of the developer solution include an alkaline aqueous solution, an organic solvent-containing liquid, and the like. As the developer solution, the organic solvent-containing liquid is preferred in light of developability and the like.

Examples of the alkaline aqueous solution include: alkaline aqueous solutions prepared by dissolving at least one alkaline compound such as sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, ethyldimethylamine, triethanolamine, tetramethylammonium hydroxide (TMAH), pyrrole, piperidine, choline, 1,8-diazabicyclo-[5.4.0]-7-undecene and 1,5-diazabicyclo-[4.3.0]-5-nonene; and the like.

The lower limit of a content of the alkaline compound in the alkaline aqueous solution is preferably 0.1% by mass, more preferably 0.5% by mass, and further more preferably 1% by mass. The upper limit of the content of the alkaline compound is preferably 20% by mass, more preferably 10% by mass, and still more preferably 5% by mass.

As the alkaline aqueous solution, an aqueous TMAH solution is preferred, and a 2.38% by mass aqueous TMAH solution is more preferred.

Examples of an organic solvent in the organic solvent-containing liquid include organic solvents similar to those exemplified in connection with the organic solvent (B) in the radiation-sensitive composition, and the like. Of these, the ester solvent is preferred, and butyl acetate is more preferred.

The lower limit of a content of the organic solvent in the organic solvent-containing liquid is preferably 80% by mass, more preferably 90% by mass, further more preferably 95% by mass, and particularly preferably 99% by mass. When the content of the organic solvent falls within the above range, a more improvement of a contrast of the rate of dissolution in the developer solution between the light-exposed regions and the light-unexposed regions is enabled. Examples of components other than the organic solvent in the organic solvent-containing liquid include water, silicone oil, and the like.

An appropriate amount of a surfactant may be added to the developer solution as needed. As the surfactant, for example, an ionic or nonionic fluorochemical surfactant, a silicone surfactant, and the like may be used.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate that is rotated at a constant speed while scanning with a developer solution-application nozzle at a constant speed; and the like.

It is preferred that, following the development, the substrate is rinsed by using a rinse agent such as water, alcohol, etc., and then dried. A procedure for the rinsing is exemplified by a procedure of continuously applying the rinse agent onto the substrate that is rotated at a constant speed (spin-coating procedure), a procedure of immersing the substrate for a given time period in the rinse agent charged in a container (dipping procedure), a procedure of spraying the rinse agent onto the surface of the substrate (spraying procedure), and the like.

### EXAMPLES

Hereinafter, the present invention is explained in detail by way of Examples, but the present invention is not limited to these Examples.

### Synthesis of (A) Metal-Containing Component

The organic acids (a) and the metal-containing compounds (b) used for synthesis of the metal-containing component (A) are listed below.

### (a) Organic Acid

a-1: methacrylic acid (pKa: 4.66)

a-2: benzoic acid (pKa: 4.21)

### Metal-Containing Compound (b)

b-1: zirconium(IV) isopropoxide

b-2: hafnium(IV).isopropoxide

b-3: zinc(II) isopropoxide

b-4: indium(III) isopropoxide

b-5: tellurium(IV) isopropoxide

b-6: lanthanum(III) oxide

b-7: yttrium(III) oxide

As described in Synthesis Examples 1 to 10 below, a metal-containing component (A) that includes one or two different metal atom(s) and includes particles containing a metal oxide as a principal component was synthesized by mixing the organic acid (a) and the metal-containing compound (b) in the presence or absence of a solvent. With respect to the metal-containing components (A-1) to (A-10) thus synthesized, the mean particle diameter was confirmed to fall within a range from 1.5 nm to 3.0 nm through measurements by the DLS method using a light scattering measurement device.

### Synthesis Example 1

A mixture obtained by mixing 8 g of the compound (a-1) and 1.5 g of the compound (b-1) was heated at 65° C. for 21 hrs. The reaction solution thus obtained was washed with ultra pure water and acetone to give the metal-containing component (A-1).

### Synthesis Example 2

A mixture solution obtained by dissolving 2.5 g of the compound (a-2) and 1.5 g of the compound (b-2) in tetrahydrofuran (THF) was heated at 65° C. for 21 hrs. The reaction solution thus obtained was washed with ultra pure water and acetone to give the metal-containing component (A-2).

### Synthesis Example 3

A mixture obtained by mixing 8 g of the compound (a-1), 0.7 g of the compound (b-1) and 0.7 g of the compound (b-3) was heated at 65° C. for 18 hrs. The reaction solution thus obtained was washed with ultra pure water and acetone to give the metal-containing component (A-3).

### Synthesis Example 4

A mixture obtained by mixing 8 g of the compound (a-1), 0.7 g of the compound (b-1) and 0.7 g of the compound (b-4) was heated at 65° C. for 6 hrs. The reaction solution thus obtained was washed with ultra pure water and acetone to give the metal-containing component (A-4).

### Synthesis Example 5

A mixture solution obtained by dissolving 2.5 g of the compound (a-2), 0.7 g of the compound (b-1) and 0.7 g of the compound (b-5) in THF was heated at 65° C. for 6 hrs. The reaction solution thus obtained was washed with ultra pure water and acetone to give the metal-containing component (A-5).

### Synthesis Example 6

A mixture obtained by mixing 8 g of the compound (a-1), 0.7 g of the compound (b-2) and 0.7 g of the compound (b-3) was heated at 65° C. for 18 hrs. The reaction solution thus obtained was washed with ultra pure water and acetone to give the metal-containing component (A-6).

### Synthesis Example 7

A mixture solution obtained by dissolving 2.5 g of the compound (a-2), 0.7 g of the compound (b-2) and 0.7 g of the compound (b-4) in THF was heated at 65° C. for 6 hrs. The reaction solution thus obtained was washed with ultra pure water and acetone to give the metal-containing component (A-7).

### Synthesis Example 8

A mixture obtained by mixing 8 g of the compound (a-1), 0.7 g of the compound (b-2) and 0.7 g of the compound (b-5) was heated at 65° C. for 6 hrs. The reaction solution thus obtained was washed with ultra pure water and acetone to give the metal-containing component (A-8).

### Synthesis Example 9

A mixture obtained by mixing 8 g of the compound (a-1), 1.5 g of the compound (b-1) and 0.2 g of the compound (b-6) was heated at 65° C. for 21 hrs. The reaction solution thus obtained was washed with ultra pure water and acetone to give the metal-containing component (A-9).

### Synthesis Example 10

A mixture solution obtained by dissolving 2.5 g of the compound (a-2), 1.5 g of the compound (b-2) and 0.2 g of the compound (b-7) in THF was heated at 65° C. for 21 hrs. The reaction solution thus obtained was washed with ultra pure water and acetone to give the metal-containing component (A-10).

### Preparation of Radiation-Sensitive Composition

The organic solvent (B) and the acid generating agent (C) which were used in the preparation of the radiation-sensitive composition are listed below.

### (B) Organic Solvent

B-1: propylene glycol monomethyl ether acetate

B-2: propylene glycol monoethyl ether

### (C) Acid Generating Agent

C-1: N-(trifluoromethylsulfonyloxy)-1,8-naphthalimide

C-2: triphenylsulfonium trifluoromethanesulfonate

### Comparative Example 1

A mixed liquid having a solid content concentration of 5% by mass was obtained by mixing 100 parts by mass (solid content equivalent) of (A-1) as the metal-containing component (A), (B-1) as the organic solvent (B), and 5 parts by mass of (C-1) as the acid generating agent (C), and then filtered through a membrane filter having a pore size of 0.20 μm to prepare a radiation-sensitive composition (R-1).

### Comparative Example 2 and Examples 1 to 8

Radiation-sensitive compositions (R-2) to (R-10) were prepared by a similar operation to that of Comparative Example 1 except that the type and the content of each component used were as shown in Table 1 below.

TABLE 1

| | | (A) Metal-containing | | | | |
|---|---|---|---|---|---|---|
| | | component | | | (C) Acid generating | |
| | | | Amount blended | (B) Organic | agent | |
| | Radiation-sensitive | | (parts by mass of | solvent | | Amount blended |
| | composition | Type | total solid content) | Type | Type | (parts by mass) |
| Comparative | R-1 | A-1 | 100 | B-1 | C-1 | 5 |
| Example 1 | | | | | | |
| Comparative | R-2 | A-2 | 100 | B-1 | C-2 | 5 |
| Example 2 | | | | | | |
| Example 1 | R-3 | A-3 | 100 | B-1 | C-1 | 5 |
| Example 2 | R-4 | A-4 | 100 | B-1/B-2 | C-1 | 5 |
| | | | | (mass ratio: 1/1) | | |
| Example 3 | R-5 | A-5 | 100 | B-1 | C-2 | 5 |
| Example 4 | R-6 | A-6 | 100 | B-1 | C-2 | 5 |
| Example 5 | R-7 | A-7 | 100 | B-1 | C-2 | 5 |
| Example 6 | R-8 | A-8 | 100 | B-1/B-2 | C-1 | 5 |
| | | | | (mass ratio: 1/1) | | |
| Example 7 | R-9 | A-9 | 100 | B-1 | C-1 | 5 |
| Example 8 | R-10 | A-10 | 100 | B-1 | C-2 | 5 |

### Pattern Formation

### Comparative Example 1

The radiation-sensitive composition (R-1) prepared above was spin-coated onto a silicon wafer by a simplified spin coater, and then subjected to PB at 100° C. for 60 sec to form a film having an average thickness of 50 nm. Next, the film was irradiated with an electron beam using an electron beam writer (“JBX-9500FS” available from JEOL, Ltd.) to permit patterning. Subsequent to the irradiation with an electron beam, the film was developed by using an organic solvent and then dried to form a negative tone pattern.

### Comparative Example 2 and Examples 1 to 8

Negative tone patterns were formed by a similar operation to that of Comparative Example 1 except that the radiation-sensitive compositions used were as shown in Table 2 below.

### Evaluations

The patterns thus formed were evaluated for the sensitivity and the limiting resolution (resolution) by the method described below. The results of the evaluations are shown together in Table 2.

### Sensitivity

An exposure dose at which a line and space pattern (1L 1S) configured with a line part having a line width of 100 nm and a space part formed by neighboring line parts with an interval of 100 nm was formed to give a line width of 1:1 was defined as “optimal exposure dose”, and the “optimal exposure dose” was defined as “sensitivity” (μC/cm²).

### Limiting Resolution

Line and space patterns (1L 1S) were formed to have various line widths, and a half-pitch of the pattern in which a total of the line widths and the space widths was the smallest among the line and space patterns having the line width of 1:1 being maintained was defined as a limiting resolution (nm).

TABLE 2

| | | | | Limiting |
|---|---|---|---|---|
| | Radiation-sensitive | PB | Sensitivity | resolution |
| | composition | (° C.) | (μC/cm²) | (nm) |
| Comparative | R-1 | 100 | 60 | 65 |
| Example 1 | | | | |
| Comparative | R-2 | 100 | 60 | 60 |
| Example 2 | | | | |
| Example 1 | R-3 | 100 | 55 | 55 |
| Example 2 | R-4 | 100 | 60 | 55 |
| Example 3 | R-5 | 100 | 60 | 55 |
| Example 4 | R-6 | 100 | 55 | 55 |
| Example 5 | R-7 | 100 | 60 | 50 |
| Example 6 | R-8 | 100 | 60 | 50 |
| Example 7 | R-9 | 100 | 55 | 55 |
| Example 8 | R-10 | 100 | 55 | 55 |

From the results shown in Table 2, the lithography performances, in particular resolution, of the radiation-sensitive composition containing the metal-containing component (A) were confirmed to be improved due to the foreign metal being mixed thereinto. The aforementioned effect is believed to be owing to, for example, the symmetry of the particles (x) that include a metal oxide as the principal component being reduced, and in turn an amorphous state suited for lithography being more likely to be maintained. It is to be noted that an exposure to an electron beam is generally known to give a tendency similar to that in the case of the exposure to EUV. Therefore, the radiation-sensitive composition of the embodiment of the present invention is expected to be superior in resolution and sensitivity also in the case of an exposure to EUV. Furthermore, by mixing metal(s) known to have high EUV absorptivity such as zinc, indium and tin, an improvement of sensitivity in the case of an exposure to EUV can also be expected.

The radiation-sensitive composition and the pattern-forming method according to the embodiments of the present invention enable a resist pattern superior in resolution to be formed with high sensitivity. Therefore, these can be suitably used for a processing process of semiconductor devices, and the like, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

1. A radiation-sensitive composition comprising:
a metal-containing component comprising particles comprising a metal oxide as a principal component; and
an organic solvent,
wherein the metal-containing component comprises at least two metal atoms which are different from one another, and
a percentage content of the at least two metal atoms with respect to an entirety of metal atoms and metalloid atoms in the composition is no less than 50 atom %.

2. The radiation-sensitive composition according to claim 1, wherein the metal-containing component comprises: a first metal atom that is at least one selected from a titanium atom, a zirconium atom, a hafnium atom, a zinc atom, a tin atom and an indium atom; and a second metal atom that is at least one selected from a lanthanum atom and an yttrium atom.

3. The radiation-sensitive composition according to claim 2, wherein a percentage content of the second metal atom with respect to an entirety of the first metal atom and the second metal atom in the composition is no less than 1 atom % and no greater than 30 atom %.

4. The radiation-sensitive composition according to claim 1, wherein the metal-containing component comprises a third metal atom that is at least two selected from a titanium atom, a cobalt atom, a nickel atom, a copper atom, a silver atom, a platinum atom, a zirconium atom, a zinc atom, a tin atom, an indium atom, a tellurium atom, a bismuth atom, an antimony atom and a hafnium atom.

5. The radiation-sensitive composition according to claim 4, wherein a percentage content of the third metal atom with respect to an entirety of metal atoms in the composition is no less than 50 atom %.

6. The radiation-sensitive composition according to claim 1 further comprising a radiation-sensitive acid generator.

7. The radiation-sensitive composition according to claim 1, wherein a mean particle diameter of the particles is no greater than 20 nm.

8. The radiation-sensitive composition according to claim 4, wherein the third metal atom is a combination of: a zirconium atom or a hafnium atom; and a zinc atom, an indium torn or a tin atom.

9. A pattern-forming method comprising:
applying the radiation-sensitive composition according to claim 1 on a substrate to form a film;
exposing the film; and
developing the film exposed.

10. The pattern-forming method according to claim 8, wherein a developer solution used in the developing is an organic solvent-containing liquid.

11. The pattern-forming method according to claim 8, wherein a developer solution used in the developing is an alkaline aqueous solution.

12. The pattern-forming method according to claim 8, wherein a radioactive ray used in the exposing is an extreme ultraviolet ray or an electron beam.
